(19) United States
(12) Patent Application Publication
(10) Pub. No.: US 2009/0108258 A1
(43) Pub. Date: Apr. 30, 2009

(54) Semiconductor Device And Method for Fabricating The Same

(76) Inventor: Hee Baeg AN, Bucheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/257,278

(22) Filed: Oct. 23, 2008

(30) Foreign Application Priority Data
Oct. 31, 2007 (KR) 10-2007-0110273

(51) Int. Cl. H01L 23/535; H01L 21/768

(52) U.S. Cl. 257/48; 438/637; 257/E23.168; 257/E21.575

(57) ABSTRACT

A semiconductor device and a method for fabricating the same are disclosed, which are capable of improving the performance and the production yield of the device. The semiconductor device may include a semiconductor wafer having semiconductor chips thereon, a lower metal layer on the semiconductor wafer, a dielectric layer on the lower metal layer, upper conductive layers on the dielectric layer, separated into a plurality of pieces; and a passivation layer enclosing lateral sides of the pieces of the upper conductive layer. Accordingly, when dicing and separating the respective chips on the semiconductor wafer, the upper metal layer does not lift off the dielectric layer. Therefore, the performance and the production yield of the semiconductor device can be enhanced.

This application claims the benefit of the Korean Patent Application No. 10-2007-0110273, filed on Oct. 31, 2007, which is hereby incorporated by reference as if fully set forth herein.

### BACKGROUND OF THE INVENTION

1. Field of the Invention

The present invention relates to a semiconductor device and a method for fabricating the same, and more particularly, to a semiconductor device capable of improving the performance and the production yield thereof, and a method for fabricating the same.

2. Discussion of the Related Art

When fabricating a semiconductor integrated circuit (IC) device, a plurality of chip areas are defined by scribe regions of a semiconductor wafer. A plurality of the semiconductor IC circuits or circuit elements are formed in each of the chip areas. On the semiconductor IC devices, a predetermined line structure may be constructed by depositing a line layer and an interlayer dielectric, in that order.

After thus constructing the semiconductor IC structure in each chip area, dicing is performed in the scribe region to thereby separate the respective chips from the wafer. Generally, the dicing is performed by a method that cuts the whole thickness of the semiconductor wafer using a dicing saw.

After completing fabrication of the semiconductor device, a fabrication process checking pattern (e.g., a test pattern) is formed among the chips so as to confirm whether the fabrication has been normally performed. Such a fabrication process checking pattern includes an upper metal layer for probing.

FIG. 1 is a plan view of a general conventional semiconductor device including a fabrication process checking (test) upper metal layer.

As shown in FIG. 1, the conventional semiconductor device 1 including the upper metal layer 40, comprises a lower metal layer (pad metal layer) 10 formed on a semiconductor wafer, and a dielectric layer 20 formed on the lower metal layer 10. The upper metal layer 40 is formed on the dielectric layer 20. In addition, a passivation layer 30 is formed around the upper metal layer 40 so as to not only separate the upper metal layer 40 from the other regions but also protect the upper metal layer 40 from external shocks. The passivation layer 30 encloses the metal layer 40 and overlaps with a periphery of the upper metal layer 40. As shown in FIG. 2, additionally, a via contact 50 penetrates the dielectric layer 20 to achieve electric contact between the lower metal layer 10 and the upper metal layer 40.

FIG. 2 is a sectional view of the semiconductor device of FIG. 1 cut along a line I-I′, where the dicing is normally performed. FIG. 3 is a sectional view of the semiconductor of FIG. 1 cut along a line I-I′, where a defect occurs during the dicing.

The semiconductor device 1 undergoes testing after being fabricated. When no defective chips are found as a result of the testing, the respective chips are separated from the semiconductor wafer. Here, the chips are cut and separated using the dicing saw, for example.

When the separation of the chips from the semiconductor wafer is successfully performed, the semiconductor device has a cross-sectional form as shown in FIG. 2. When adhesive force between the upper metal layer 40 and the dielectric layer 20 is insufficient, however, the upper metal layer 40 may separate from or peel off the dielectric layer 20 as shown in FIG. 3 during the cutting.

In this case, the upper metal layer 40 may be brought in contact with other parts, thereby causing defects (apparent or real) in the semiconductor device. As a result, performance of the semiconductor device and/or productivity and/or yield in the manufacturing method may deteriorate.

### SUMMARY OF THE INVENTION

Accordingly, the present invention is directed to a semiconductor device and a method for fabricating the same that substantially obviate one or more problems due to limitations and disadvantages of the related art.

An object of the present invention is to provide a semiconductor device or wafer preventing an upper metal layer, which may be a pad metal layer, from being lifted off a dielectric layer during cutting of chips on a semiconductor wafer, thereby improving the performance and/or the production yield of the semiconductor device, and a method for fabricating the same.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, a semiconductor wafer may comprise a plurality of semiconductor chips thereon, a lower metal layer on the semiconductor wafer, a dielectric layer on the lower metal layer, a plurality of upper conductive layers on the dielectric layer, separated into a plurality of pieces, and a passivation layer enclosing at least four lateral sides of the respective pieces of the upper conductive layer.

According to another embodiment of the present invention, the semiconductor wafer comprises a plurality of semiconductor chips thereon, a lower metal layer on the semiconductor wafer, a dielectric layer on the lower metal layer, a plurality of separate upper conductive pieces on the dielectric layer, and a passivation layer enclosing lateral sides and upper peripheral surfaces of the respective upper conductive pieces.

According to embodiments of the present invention, the plurality of upper conductive layers comprise a metal or non-metal. The plurality of upper conductive layers may have the same surface area as adjoining or adjacent upper conductive layers or different surface areas from adjoining or adjacent upper conductive layers.

The passivation layer may comprise an adhesive material.

The semiconductor device or wafer may further comprise a plurality of via contacts penetrating the dielectric layer to achieve electric connection between the lower metal layer and the respective upper conductive layers.

In another aspect of the present invention, a method for fabricating a semiconductor device comprises: forming a lower metal layer on a semiconductor wafer, forming a dielectric layer on the lower metal layer, forming a conductive layer by vapor-depositing a conductive material on the whole surface of the dielectric layer, forming a plurality of upper conductive layers by patterning the conductive layer, forming a film layer by applying an adhesive film material on the plurality of upper conductive layers, forming a photoresist pattern on the film layer, and forming a passivation layer enclosing at least four lateral sides of the respective upper conductive layers by patterning the film layer through an etching process using the photoresist pattern as a mask.

The semiconductor device fabricating method according to another embodiment of the present invention comprises forming a lower metal layer on a semiconductor wafer, forming a dielectric layer on the lower metal layer, forming a conductive layer by vapor-depositing a conductive material on the whole surface of the dielectric layer, forming a plurality of upper conductive layers by patterning the metal layer, forming a film layer by applying an adhesive film material on the plurality of upper conductive layers, forming a photoresist pattern on the film layer, and forming a passivation layer enclosing at least four lateral sides and upper peripheral surfaces of the respective upper conductive layers by etching the film layer using the photoresist pattern as a mask.

The fabricating method may further comprise forming a photoresist pattern on the dielectric layer, forming a contact hole by etching the dielectric layer using the photoresist pattern as a mask, and forming a plurality of via contacts by vapor-depositing or implanting a conductive material in the contact hole so that the lower metal layer is subsequently electrically connected to the respective upper conductive layer(s).

Here, the etching process may comprise plasma etching. Upper surfaces of the respective upper conductive layers may be totally or partly exposed by the etching process.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and along with the description serve to explain the principle(s) of the invention. In the drawings:

FIG. 1 is a plan view of a conventional semiconductor device including a fabrication process checking (test) structure;

FIG. 2 is a sectional view of the semiconductor device cut along a line I-I′ of FIG. 1, where the dicing is normally performed;

FIG. 3 is a sectional view of the semiconductor cut along a line I-I′ of FIG. 1, where a defect is generated during the dicing;

FIG. 4 is a plan view of a semiconductor device formed with a plurality of upper conductive layers, according to first and second embodiments of the present invention;

FIG. 5 is a sectional view of the semiconductor device shown in FIG. 4 according to the first embodiment, cut along a line II-II′;

FIG. 6 is a sectional view of the semiconductor device shown in FIG. 4 according to the second embodiment, cut along a line II-II′; and

FIGS. 7A through 7D are sectional views showing exemplary processes of a fabricating the semiconductor device according to embodiment(s) of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

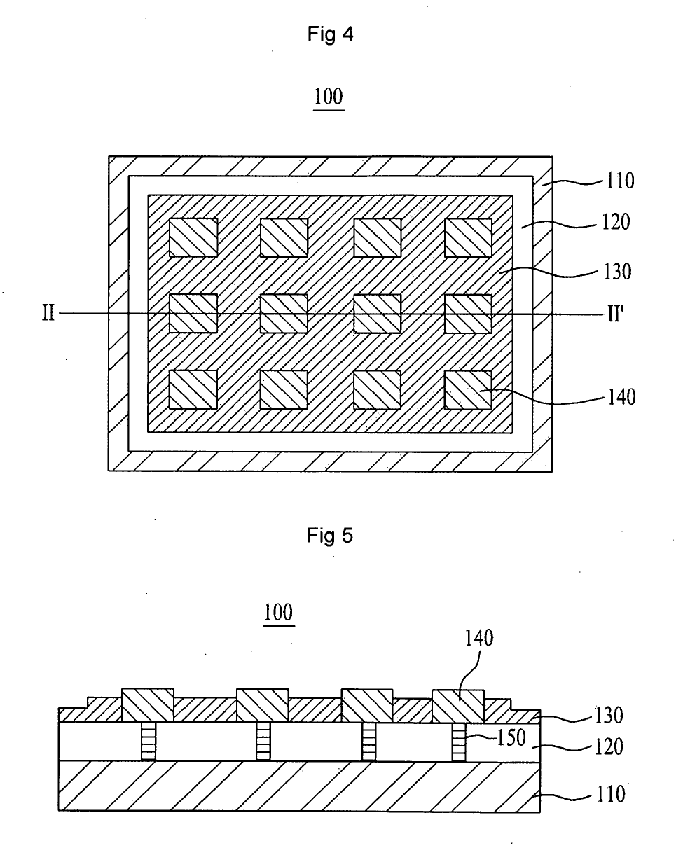

FIG. 4 is a plan view of a semiconductor device formed with a plurality of upper conductive layers, according to first and second embodiments of the present invention.

Referring to FIG. 4, the semiconductor device 100 according to the embodiments of the present invention comprises a semiconductor wafer whereon a plurality of chips are formed, a lower metal layer 110 formed on the semiconductor wafer, a dielectric layer 120 formed on the lower metal layer 110, a plurality of upper conductive layers 140 formed on the dielectric layer 120 for probing of the plurality of chips formed on the semiconductor wafer, and a passivation layer 130 formed to enclose four lateral sides of each of the plurality of upper conductive layers 140. Of course, the plurality of upper conductive layers 140 may have other shapes, such as polygonal, L-shaped, T-shaped, H-shaped, round or oval, and as such, the passivation layer 130 may enclose a lateral periphery or circumference of each upper conductive layer 140.

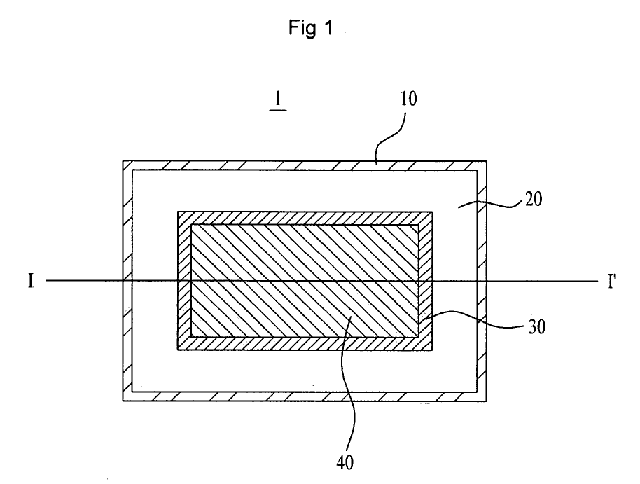

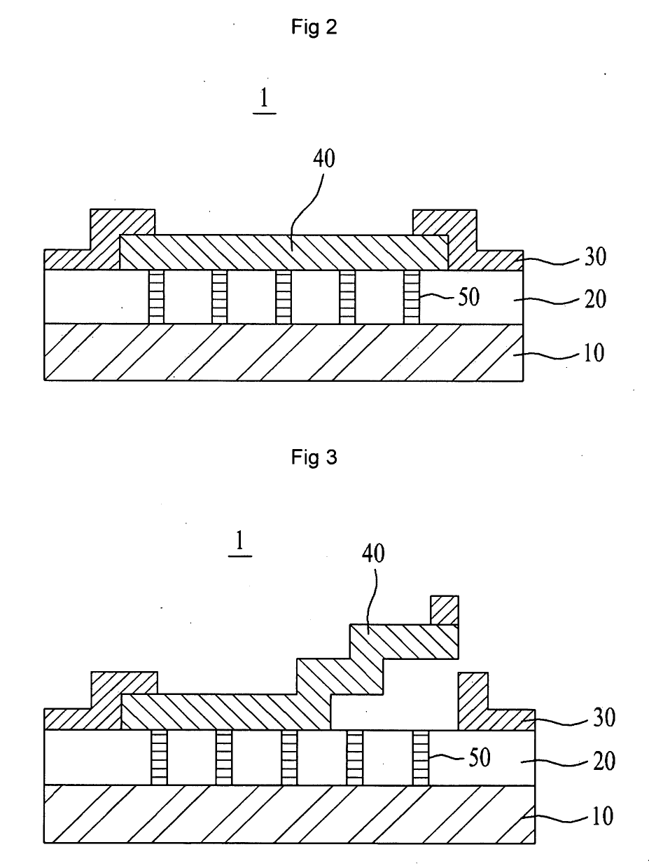

In the conventional semiconductor device 1 shown in FIG. 1, the upper conductive layer 40 occupies a relatively large area on the semiconductor wafer. However, in the semiconductor device 100 according to the embodiments of the present invention as shown in FIG. 4, the upper conductive layer 140 is separated into a plurality of relatively small pieces on the semiconductor wafer.

Here, the upper conductive layer 140 comprises a conductive metal or conductive non-metal material. Conductive metals include titanium, tantalum, aluminum, copper, silver, gold, and alloys thereof. Conductive non-metals include titanium nitride, tantalum nitride, tungsten nitride, and silicides of Ti, Ta, Mo, W, Ni, Pt, Pd, and Co. The plurality of pieces of the upper conductive layer 140 may have the same area as adjoining or adjacent upper conductive layers 140, or respectively different areas according to the device being fabricated.

Around the respective pieces of the upper conductive layer 140, the passivation layer 130 is formed to electrically separate the pieces from the other pieces and protect the pieces from external shocks. As shown in FIG. 4 and FIG. 5, the passivation layer 130 may enclose or encompass lateral sides of the upper conductive layer 140.

Additionally, as shown in FIG. 5, a plurality of via contacts 150 are formed, penetrating the dielectric layer 120 so that the lower metal layer 110 and the respective pieces of the upper conductive layers 140 electrically connect with each other.

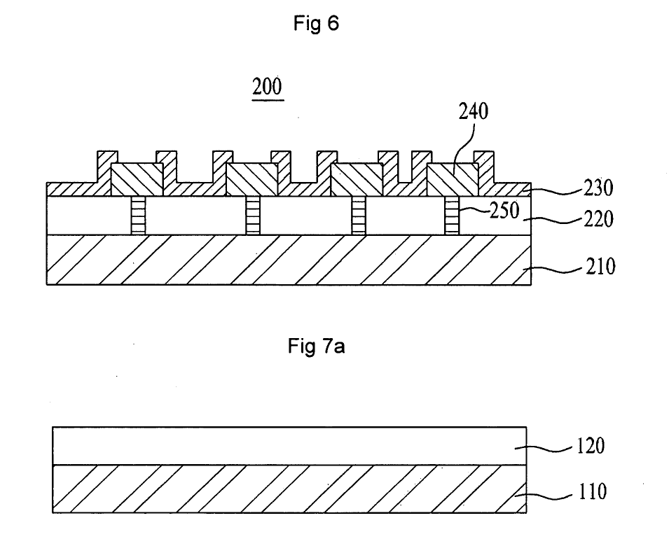

Although the passivation layer 130 of the semiconductor device 100 has been illustrated and explained as enclosing the lateral sides of the upper conductive layer 140 with reference to FIG. 5, a passivation layer 230 may be overlapped with peripheries of the upper conductive layers 240 while also enclosing four lateral sides of the upper conductive layers 240 as shown in FIG. 6 in order to improve adhesive force between the upper conductive layer 240 and the passivation layer 230.

The passivation layer 130 is formed by applying an adhesive film among the respective pieces of the upper conductive layer 140. In some embodiments, the adhesive film may comprise an organic polymer, such as a polyacrylate resist, a polyimide, or a non-conductive adhesive paste. In other embodiments, the adhesive film may comprise an inorganic material, such as silicon dioxide, silicon nitride, silicon oxynitride, or a combination thereof. By contacting the lateral sides of the plurality of pieces of the upper conductive layer 140, the passivation layer 130 prevents separation of the upper conductive layer 140 from the dielectric layer 120.

After fabrication of the semiconductor device is thus completed with the above structure, the respective chips on the semiconductor wafer are diced and separated by a dicing saw. Here, according to various embodiments, separation of the upper conductive layer 140 from the dielectric layer 120 can be prevented, which has happened in conventional devices. Accordingly, the performance and the production yield of the semiconductor device can be improved.

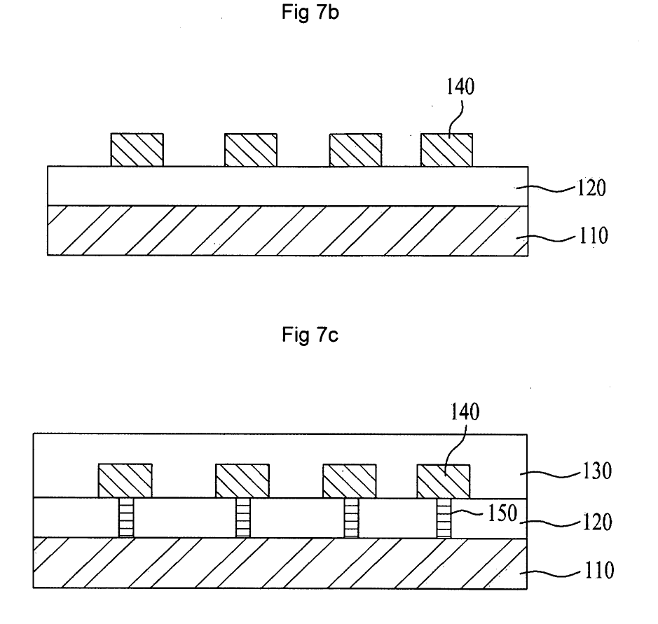

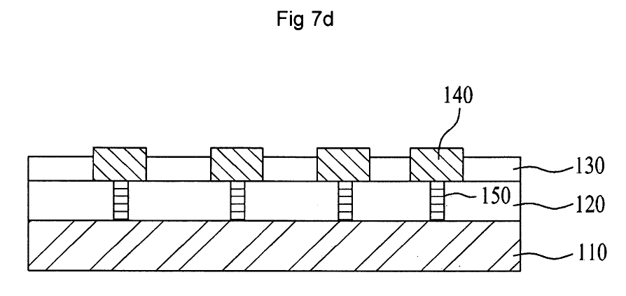

FIG. 7A through FIG. 7D are sectional views illustrating an exemplary method for fabricating the semiconductor device, according to embodiments of the present invention. Hereinafter, the fabrication method of the semiconductor device will be described referring to FIG. 7A to FIG. 7D.

Referring to FIG. 7A, first, the lower metal layer 110 is formed on the semiconductor wafer. The lower metal layer 110 may comprise one or more lowermost adhesive and/or diffusion barrier layers (e.g., titanium, titanium nitride, tantalum, tantalum nitride, etc., such as a titanium nitride-on-titanium bilayer), a bulk conductive layer (e.g., aluminum, an aluminum alloy [e.g., Al with from 0.5 to 4 wt. % Cu, up to 2 wt. % Ti, and/or up to 1 wt. % Si], or copper), and/or one or more uppermost adhesive, hillock prevention and/or antireflective coating layers (e.g., titanium, titanium nitride, titanium tungsten alloy, etc., such as a titanium nitride-on-titanium bilayer). The lower metal layer 110 (and any individual sublayers thereof) may be formed by sputtering, evaporation or chemical vapor deposition. The dielectric layer 120 is formed on the lower metal layer 110 for insulation among patterns that will be formed later. The dielectric layer 120 may comprise a plurality of insulating sublayers (not shown), each of which may independently comprise a lowermost etch stop layer (e.g., silicon nitride), one or more conformal and/or gap-fill dielectric layers (e.g., TEOS, plasma silane, or silicon-rich oxide), one or more bulk dielectric layers (e.g., silicon oxycarbide [SiOC], which may be hydrogenated [e.g., SiOCH]; undoped silicon dioxide [e.g., USG or a plasma silane]; or silicon dioxide doped with fluorine [e.g., FSG] or boron and/or phosphorous [e.g., BSG, PSG, or BPSG]), and/or one or more cap layers (e.g., TEOS, USG, plasma silane, etc.).

In order to form the via contact 150 that achieves electric connection between the lower metal layer and the plurality of pieces of the upper conductive layer 140 that will be formed later, a photoresist pattern is formed by applying a photoresist material on the dielectric layer 120 and performing photolithography on the photoresist material and developing to form a pattern. Next, etching is performed using the photoresist pattern as a mask, thereby forming a plurality of contact holes. The plurality of via contacts 150 are formed by vapor-depositing or implanting a conductive material in the contact hole. More specifically, the via contacts 150 are formed corresponding to the respective upper conductive layers 140 so that the lower metal layer 110 can be electrically connected to the respective upper conductive layers 140.

A conductive (e.g., metal) layer is formed by vapor-depositing conductive metal on the whole surface of the dielectric layer 120. Alternatively, the conductive layer may be formed by sputtering or evaporation. A photoresist material is applied to the whole surface of the conductive layer, and photolithography is performed, thereby forming a photoresist pattern.

After this, etching is performed using the photoresist pattern as a mask, accordingly patterning the conductive layer on the dielectric layer 120 into a plurality of pieces. Here, both wet etching and dry etching are applicable. According to one embodiment, plasma etching is performed in patterning the metal layer on the dielectric layer 120 into pieces.

Next, as shown in FIG. 7B, the photoresist material remaining on the semiconductor wafer is removed, and the plurality of upper conductive layers 140 generally correspond to the lower metal layer 110 on the semiconductor wafer. As aforementioned, the lower metal layer 110 is in electric connection with respective upper conductive layers 140.

Referring to FIG. 7C, an adhesive film is applied on the plurality of upper conductive layers 140. A photoresist material is applied on the whole surface of the adhesive film layer, and then photolithography is performed to thereby form a photoresist pattern.

Next, the adhesive film layer formed on the plurality of upper conductive layers 140 is patterned by performing etching with the photoresist pattern used as a mask. Through those processes, the plurality of upper conductive layers 140 are exposed as shown in FIG. 7D. Here, both wet etching and dry etching can be applied. According to this embodiment, the adhesive film layer on the upper conductive layers 140 is patterned and exposed by plasma etching.

As a consequence, the adhesive film material is formed among the respective pieces of the upper conductive layer 140, enclosing the pieces of the upper conductive layer 140. That is, the passivation layer 130 may enclose the lateral periphery or circumference of the upper conductive layers 140.

Next, the semiconductor wafer is diced or cut to form the plurality of chips and complete the fabricating process of the semiconductor device.

According to the semiconductor device 100 according to the first embodiment of the present invention and the method for fabricating the same, since the upper conductive layer 140 can be prevented from separating from the dielectric layer 120 during the cutting of the chips on the wafer, the performance and the production yield of the semiconductor device can be improved.

Although the structure in which the passivation layer 130 encloses the four lateral sides of the upper conductive layer 140 and the method for fabricating the same have been explained, the passivation layer 230 may overlap with an upper surface of the peripheries of the upper conductive layers 240 while enclosing the sides of the upper conductive layers 240 as shown in FIG. 6 in order to improve adhesive force between the upper conductive layer 240 and the passivation layer 230.

According to the method for fabricating the latter structure, all the processes of FIGS. 7A to 7D are performed in the same manner except that in the process of FIG. 7D, the adhesive film layer applied to the plurality of upper conductive layers 140 is patterned differently.

More specifically, in the process of forming the photoresist pattern by applying the photoresist material onto the adhesive film layer on the plurality of upper conductive layers 140 and performing photolithography, the photoresist pattern is formed such that the adhesive film layer covers upper peripheries of the respective upper conductive layers 240 as shown in FIG. 6, instead of totally exposing the upper conductive layers 140 as shown in FIG. 5.

Then, etching is performed using the photoresist pattern as a mask so that the adhesive film layer (that is, the passivation layer 230 formed on the upper conductive layers 240) is patterned to enclose the lateral sides of the upper conductive layers 240, overlapping with the peripheries of the upper conductive layers 240. By this, as shown in FIG. 6, upper surfaces of the respective upper conductive layers 240 are partly exposed.

Next, the photoresist pattern remaining on the passivation layer 230 and the upper conductive layers 240 is removed.

Here, wet etching and dry etching are both applicable. The present embodiment may pattern the adhesive film layer on the plurality of upper conductive layers 240 by plasma etching, thereby partly exposing the upper surfaces of the respective upper conductive layers 240. Accordingly, the adhesive film layer encloses the lateral sides among the respective upper conductive layers 240 and the upper peripheries of the upper conductive layers 240. That is, by enclosing the lateral sides and the upper peripheries of the respective upper conductive layers 240, the passivation layer 230 enhances the adhesive force between the upper conductive layers 240 and the dielectric layer 220.

Afterwards, the plurality of chips formed on the semiconductor wafer are diced or cut, thereby fabricating the semiconductor device.

In accordance with a semiconductor device 200 according to the second embodiment of the present invention and a method for fabricating the same, since the upper conductive layers 240 are prevented from separating from the dielectric layer 220 during cutting or dicing of the chips on the wafer, the performance and the production yield of the semiconductor device can be improved.

As apparent from the above description, in a semiconductor device according to the above-described embodiments of the present invention, an upper conductive layer on a semiconductor wafer is separated into small pieces, and sides of the respective pieces of the upper conductive layer are enclosed or encompassed by a passivation layer. Accordingly, when dicing and separating the respective chips on the semiconductor wafer using a dicing saw, the upper conductive layer can remain on an underlying dielectric layer. Therefore, the performance and the production yield of the semiconductor device can be enhanced.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A semiconductor wafer comprising:
a plurality of semiconductor chips thereon;
a lower metal layer on the semiconductor wafer;
a dielectric layer on the lower metal layer;
a plurality of upper conductive layers on the dielectric layer, separated into a plurality of pieces; and
a passivation layer enclosing at least four lateral sides of the respective pieces of the upper conductive layer.

2. The semiconductor wafer according to claim 1, wherein the plurality of upper conductive layers comprise a metal or non-metal.

3. The semiconductor wafer according to claim 1, wherein the plurality of upper conductive layers respectively have the same surface area as adjoining ones.

4. The semiconductor wafer according to claim 1, wherein the plurality of upper conductive layers respectively have different surface areas from adjoining ones.

5. The semiconductor wafer according to claim 1, wherein the passivation layer comprises an adhesive material.

6. The semiconductor wafer according to claim 1, wherein the passivation layer further encloses upper peripheral surfaces of the respective upper conductive layers.

7. The semiconductor wafer according to claim 1, further comprising a plurality of via contacts penetrating the dielectric layer to achieve electric connection between the lower metal layer and the respective upper conductive layer(s).

8. The semiconductor wafer according to claim 1, further comprising scribe lanes defining regions where the plurality of semiconductor chips are located, and the lower metal layer, the dielectric layer, the upper conductive layers, and passivation layer are in the scribe lane.

9. The semiconductor wafer according to claim 8, wherein the lower metal layer, the dielectric layer, and the upper conductive layers define a test structure for checking a process for fabricating the semiconductor wafer.

10. A method for fabricating a semiconductor wafer, comprising:
forming a lower metal layer on a semiconductor wafer;
forming a dielectric layer on the lower metal layer;
forming a conductive layer by vapor-depositing a conductive material on the whole surface of the dielectric layer;
forming a plurality of upper conductive layers by patterning the conductive layer;
forming a film layer by applying an adhesive film material on the plurality of upper conductive layers;
forming a photoresist pattern on the film layer; and
forming a passivation layer enclosing four lateral sides of the respective upper conductive layers by patterning the film layer through an etching process using the photoresist pattern as a mask.

11. The fabricating method according to claim 10, wherein the conductive material is metal or non-metal.

12. The fabricating method according to claim 10, wherein the plurality of upper conductive layers respectively have the same surface area as adjoining ones.

13. The fabricating method according to claim 10, wherein the plurality of upper conductive layers respectively have different surface areas from adjoining ones.

14. The fabricating method according to claim 10, wherein the passivation layer encloses upper peripheral surfaces of the upper conductive layers as well as the lateral sides of the upper conductive layers.

15. The fabricating method according to claim 10, further comprising:
forming a photoresist pattern on the dielectric layer;
forming a contact hole by etching the dielectric layer using the photoresist pattern as a mask; and
forming a plurality of via contacts by vapor-depositing or implanting a conductive material in the contact hole so that the lower conductive layer is subsequently electrically connected to the respective upper conductive layer(s).

16. The fabricating method according to claim 10, wherein the etching process comprises plasma etching.

17. The fabricating method according to claim 16, wherein upper surfaces of the respective upper conductive layers are totally or partly exposed by the etching process.

18. The fabricating method according to claim 15, wherein the etching process comprises plasma etching.

19. The fabricating method according to claim 18, wherein upper surfaces of the respective upper conductive layers are totally or partly exposed by the etching process.
